(19) United States
(12) Patent Application Publication
(10) Pub. No.: US 2025/0070723 A1
(43) Pub. Date: Feb. 27, 2025

(54) AMPLIFIER CIRCUIT AND METHOD OF GENERATING AN AMPLIFIED SIGNAL

(71) Applicant: Sony Semiconductor Solutions Corporation, Atsugi-shi, Kanagawa (JP)

(72) Inventors: Jingchu HE, Delft (NL); Morteza ALAVI, Delft (NL); Martin FRITZ, Stuttgart (DE); Masoud BABAIE, Delft (NL); Zhong GAO, Delft (NL); Bogdan STASZEWSKI, Delft (NL)

(73) Assignee: Sony Semiconductor Solutions Corporation, Atsugi-shi, Kanagawa (JP)

(21) Appl. No.: 18/726,964

(22) PCT Filed: Jan. 3, 2023
(86) PCT No.: PCT/EP2023/050048

§ 371 Date: Jul. 5, 2024

(30) Foreign Application Priority Data
Jan. 12, 2022 (EP) 22151145.4

(51) Int. Cl. H03F 1/02; H03F 3/00; H03F 3/217; H03F 3/24

(52) U.S. Cl. CPC H03F 1/0288; H03F 3/005; H03F 3/2171; H03F 3/2178; H03F 3/245; H03F 2200/09; H03F 2200/541

(57) ABSTRACT

The present disclosure relates to an amplifier circuit comprising a main amplifier circuit comprising a plurality of first switched-capacitor, SC, house-of-cards, HoC, amplifier cells coupled in parallel between an input and an output of the main amplifier circuit, at least one peak amplifier circuit comprising a plurality of second SC HoC amplifier cells coupled in parallel between an input and an output of the peak amplifier circuit, wherein the output of the main amplifier circuit and the output of the peak amplifier circuit are coupled to a common load.

### FIELD

The present disclosure generally relates to power amplifiers and, more particularly, to a combination of voltage-mode Doherty amplifier and house-of-cards (HoC) power amplifier concepts.

### BACKGROUND

Modern wireless communication systems employ spectral-efficient modulation schemes to boost their data throughput. These modulation schemes feature a high peak-to-average power ratio (PAPR) (e.g., >10 dB) that demands a digital transmitter (DTX) to operate in deep power back-off, degrading its system efficiency considerably. Power back-off in an amplifier refers to a power level below the saturation point at which the amplifier will continue to operate in the linear region even if there is a slight increase in the input power level. Usually, power amplifiers operate close to the saturation point as that is where efficiency is maximum. However, at this point, a small increase in input power can push the amplifier from the linear mode to the saturated mode.

Various efficiency enhancement techniques, such as Doherty power amplifiers, out-phasing, and supply modulation techniques, are currently adopted in DTX architectures to improve efficiency at power back-off. The Doherty power amplifier topology is popular among them due to its less complicated baseband processing and power combiner topology, and most importantly, handling large modulation and radio frequency (RF) bandwidth. The classical Doherty power amplifier topology is composed of main power amplifier, a peaking power amplifier, and an impedance inverter. Nevertheless, prevailing fully integrated digital two-way Doherty power amplifiers do not enhance efficiency beyond their typical 6 dB power-back-off (PBO).

On the other hand, switched-capacitor power amplifiers (SCPA) are widely adopted in digital-intensive transmitters (TX) with non-efficient operation at power-back-off, resulting in significant power consumption for battery-based Internet of Things (IoT) devices. To address this issue, a voltage mode Doherty (VMD)-based SCPA architecture eliminating the narrowband impedance inverter used in a conventional Doherty PA has been proposed. Its basic schematic is shown in FIG. 1.

The voltage-mode amplifier can be efficiently realized at gigahertz frequencies with a SCPA. In an SCPA, a voltage-mode class-D power amplifier may be segmented into smaller unit cells, and the output voltage may be digitally controlled by turning on a subset of the unit cells. A transformer balun 12 coupled between a main power amplifier 14 and a peaking power amplifier 16 drives a single ended load. The principle of operation is as follows: at low power, the peaking power amplifier 16 is OFF providing a short circuit at the bottom side of the primary of the balun 12. Under this condition, the main power amplifier 14 sees a load impedance R_{L} and saturates at 6-dB back-off. The peaking power amplifier 16 is then turned on, driving the balun 12 in antiphase (180°) relative to the main power amplifier 14 and giving V_{load}=Vₘ+Vₚ (where V_{load}, Vₘ, and Vₚ are voltage amplitudes at the fundamental for load, main, and peaking power amplifiers), as well as increasing the current through the main power amplifier 14. While the current provided by the main power amplifier 14 increases due to the peaking power amplifier 16, the voltage the main power amplifier 14 presents to the balun 12 does not increase, so the impedance seen by the main power amplifier 14 decreases as Rₘ=R_{L}/(1+Vₚ/Vₘ). This allows the main power amplifier 14 to provide more power to the load while remaining in saturation, and maintains overall high efficiency from 6-dB back-off to peak power.

Alternatively, house-of-cards (HoC) power amplifiers have been introduced to improve digital power amplifier (DPA) efficiency. As depicted in FIG. 2, the idea of a HoC power amplifier is to stack CMOS (complementary metal-oxide-semiconductor) inverters and drive them appropriately to replicate a Doherty-like behavior without using a passive impedance inverter. FIG. 2 shows a switched-capacitor (SC) house-of-cards (HoC) amplifier cell 20 comprising a first CMOS inverter 22-1 coupled between V_{DD} and ground potential. A first control voltage Vᵢₙ₁ is coupled to the gates of the P- and N-channel field-effect transistors (FETs) of the first CMOS inverter 22-1. Further, a first capacitor Cᵢₙₜ is coupled between V_{DD} and ground potential and hence between the source terminals of the P- and NMOS transistors of the first CMOS inverter 22-1. A second CMOS inverter 22-2 is stacked on top of the first inverter 22-1 and coupled between 2V_{DD} and V_{DD}. A second control voltage Vᵢₙ₂ is coupled to the gates of the P- and NMOS transistors of the second CMOS inverter 22-2. Further, a second capacitor Cᵢₙₜ is coupled between 2V_{DD} and V_{DD} and hence between the source terminals of the P- and NMOS transistors of the second CMOS inverter 22-2. A third or final CMOS inverter 22-3 is coupled between the outputs of the second and first CMOS inverters 22-2, 22-1. The intermediate V_{DD} node between 2V_{DD} and ground is coupled to the gates of the P- and NMOS transistors of the final CMOS inverter 22-3. A third capacitor Cᵢₙₜ is coupled between the outputs of the second and first CMOS inverters 22-2, 22-1 and hence between the source terminals of the P- and NMOS transistors of the final CMOS inverter 22-3. The output of the final CMOS inverter 22-3 is coupled to a (switched) capacitor 24. Capacitor 24 is coupled between a load 26 and an output of the final CMOS inverter 22-3. While the first and the second CMOS inverters 22-1, 22-2 may be regarded as a base of a HoC circuit topology, the final CMOS inverter 22-3 may be regarded as a tip of the HoC circuit topology. The HoC circuit topology includes stacked power amplifiers (e.g., class D power amplifier cells) 22-1, 22-2, 22-3 in a ladder arranged in a house-of-cards topology such that the number of stacked-domains follows a decaying triangular series M, M−1, M−2, . . . , M−i from a fixed ladder to an ith ladder to provide a 1:(i+1) voltage conversion ratio. Each stacked domain outputs its power via a flying domain power amplifier cell, and each ladder balances stacked domains of a prior ladder and combines power from all prior ladders. In the basic example of FIG. 2, M=2.

It has been demonstrated that the efficiency of the HoC circuit topology at 6 dB PBO does not suffer from the various loss mechanisms as in VMD architectures, giving rise to an improved system efficiency at PBO. Nonetheless, as mentioned earlier, the high PAPR requires an efficiency boost at deep PBO, e.g., >10 dB.

Consequently, improved next-generation DTXs are desired.

### SUMMARY

This desire is met by methods and amplifier circuits in accordance with the independent claims. Possibly advantageous embodiments are addressed by the dependent claims.

According to a first aspect, the present disclosure provides an amplifier circuit comprising a main amplifier circuit and at least one peak(ing) amplifier circuit. The main amplifier circuit comprises a plurality of first switched-capacitor (SC) house-of-cards (HoC) amplifier cells coupled in parallel between an input and an output of the main amplifier circuit. The at least one peak amplifier circuit comprises a plurality of second SC HoC amplifier cells coupled in parallel between an input and an output of the peak amplifier circuit. The output of the main amplifier circuit and the output of the peak amplifier circuit are coupled to a common load.

According to a second aspect, the present disclosure provides a method of generating an amplified signal. The method includes generating a first amplifier output signal using a main amplifier circuit comprising a plurality of parallel first switched-capacitor (SC) house-of-cards (HoC) amplifier cells, generating a second amplifier output signal using at least one peak amplifier circuit comprising a plurality of parallel second SC HoC amplifier cells, and coupling the first and second amplifier output signals to a common load.

The present disclosure addresses a digital power amplifier (DPA) which may be utilized in the amplitude modulation (AM) path of digital polar transmitters, for example. Embodiments may comprise an M-stacked house-of-cards structure configured in a voltage-mode Doherty (VMD) switched-capacitor power amplifier (SCPA) topology to boost its system efficiency in deep power back-off. The proposed DPA structure can be adopted in all digital transmitter systems entailing a DPA as their final stage.

### BRIEF DESCRIPTION OF THE FIGURES

Some examples of apparatuses and/or methods will be described in the following by way of example only, and with reference to the accompanying figures, in which

FIG. 1 shows a conventional voltage mode (VMD) Doherty switched capacitor (SC) power amplifier;

FIG. 2 shows a conventional House-of-Cards (HoC) switched capacitor (SC) power amplifier;

FIG. 3 shows an amplifier circuit according to an embodiment of the present disclosure;

FIG. 4 shows a stacked HoC SC power amplifier architecture used in embodiments of the present disclosure;

FIG. 5 illustrates an operation of 3-stacked HoC SC power amplifier with different gate drive;

FIG. 6 shows an operation of the proposed 3-stacked HoC SC power amplifier;

FIG. 7 illustrates a lossless efficiency of a 3-stacked HoC SC power amplifier;

FIG. 8 shows an operation of a proposed 3-stacked VMD HoC SC power amplifier in VMD-HoC-VMD mode;

FIG. 9 illustrates a 6-way HoC-VMD lossless efficiency vs PBO;

FIG. 10 illustrates a push-pull implementation of an amplifier circuit according to an embodiment of the present disclosure;

FIG. 11 illustrates an operation of the proposed 3-stacked VMD HoC SC power amplifier in HoC-VMD-HoC mode;

FIG. 12 shows an example of a mixing operation for HoC+VMD SC power amplifier in a polar DTX;

FIG. 13 shows a lossless efficiency versus output power for different power amplifier architectures;

FIG. 14 shows an efficiency comparison between proposed architecture and state-of-art structure; and

FIG. 15 shows an example of an 8-way VMD HoC SC power amplifier architecture with 4-stacked VDD HoC HoC SC power amplifiers according to an embodiment of the present disclosure.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

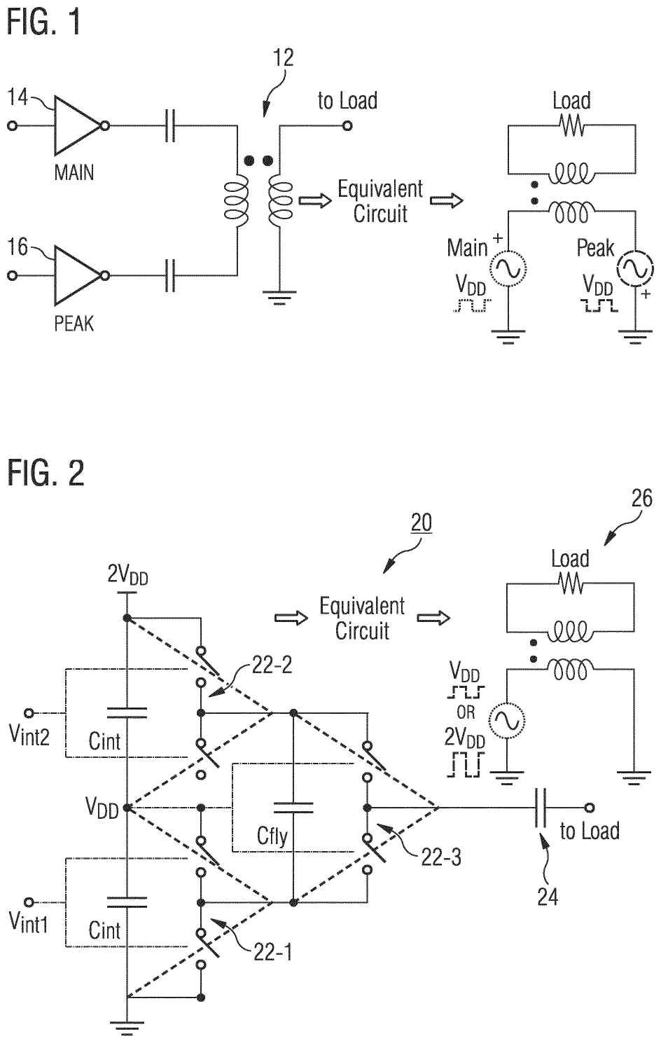

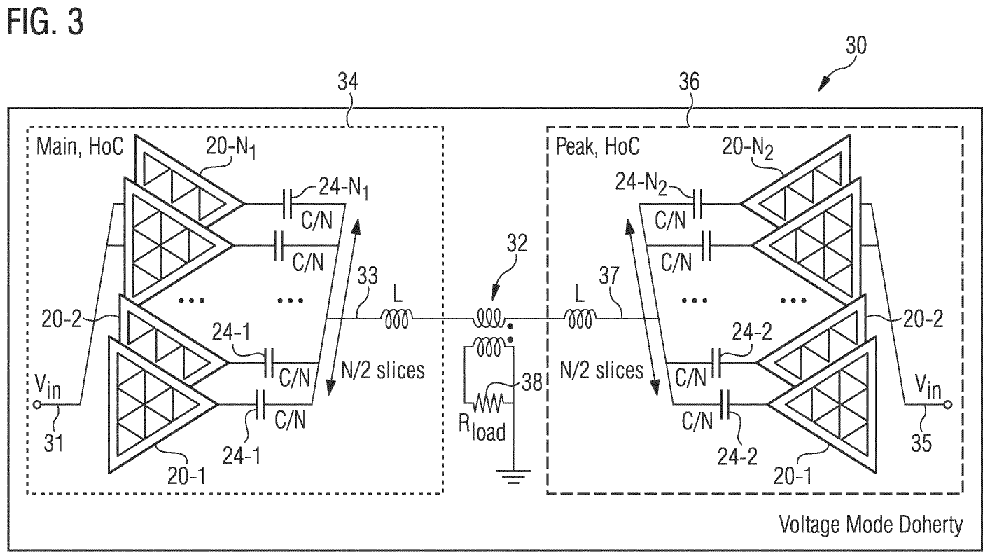

The voltage-mode Doherty (VMD) concept of FIG. 1 may be combined with an M-stacked HoC architecture of FIG. 2 to obtain a voltage-mode Doherty (VMD) switched-capacitor amplifier circuit 30 in accordance with the present disclosure. The topology of amplifier circuit 30 is illustrated in FIG. 3.

Amplifier circuit 30 comprises a main amplifier circuit 34 which comprises a plurality of first (or main) switched-capacitor (SC) house-of-cards (HoC) amplifier cells 20-1, 20-2, . . . , 20-N₁ coupled in parallel between an input 31 and an output 33 of the main amplifier circuit 34. Amplifier circuit 30 further comprises at least one peak amplifier circuit 36 which comprises a plurality of second (or peak) SC HoC amplifier cells 20-1, 20-2, . . . , 20-N₂ coupled in parallel between an input 35 and an output 37 of the peak amplifier circuit 36. The output 33 of the main amplifier circuit 34 and the output 37 of the peak amplifier circuit 36 are coupled to a common load 38.

In the illustrated embodiment, the output 33 of the main amplifier circuit 34 and the output 37 of the peak amplifier circuit 36 are coupled to the common load 38 via a transformer balun 32. Both outputs 33, 37 may be coupled to a primary side of balun 32 via respective coils (inductances).

In a minimum configuration, each of the SC HoC amplifier cells 20 of the main amplifier circuit 34 as well as of the peak amplifier circuit 36 may have the 2-stacked SC HoC (M=2) architecture of FIG. 2. That is, each SC HoC amplifier cell 20 may comprise a first CMOS inverter unit 22-1 coupled between V_{DD} and ground potential. A first control voltage Vᵢₙ₁ may be coupled to the gates of the P- and NMOS transistors of the first CMOS inverter unit 22-1. Further, a first capacitor Cᵢₙₜ may be coupled between V_{DD} and ground potential and hence between the source terminals of the P- and NMOS transistors of the first CMOS inverter unit 22-1. A second CMOS inverter unit 22-2 may be stacked on top of first CMOS inverter unit 22-1. In other words, second CMOS inverter unit 22-2 may be coupled in series to first CMOS inverter unit 22-1 (e.g., source terminal of PMOS transistor of first CMOS inverter unit 22-1 may be coupled to source terminal of NMOS transistor of second CMOS inverter unit 22-2). Thus, second CMOS inverter unit 22-2 may be coupled between 2V_{DD} and V_{DD}. A second control voltage Vᵢₙ₂ may be coupled to the gates of the P- and NMOS transistors of the second CMOS inverter unit 22-2. Further, a second capacitor Cᵢₙₜ may be coupled between 2V_{DD} and V_{DD} and hence between the source terminals of the P- and NMOS transistors of the second CMOS inverter unit 22-2. A final CMOS inverter unit 22-3 may be coupled between the outputs of the second and first CMOS inverters 22-2, 22-1. The intermediate V_{DD} node may be coupled to the gates of the P- and NMOS transistors of the final CMOS inverter unit 22-3. A third (flying) capacitor C_{fly} may be coupled between the outputs of the second and first CMOS inverters 22-2, 22-1 and hence between the source terminals of the P- and NMOS transistors of the final CMOS inverter unit 22-3. The output of final CMOS inverter unit 22-3 may be coupled to a respective (switched) capacitor 24. Capacitors 24 may be coupled between load 38 and the respective SC HoC amplifier cells 20.

In some embodiments, each of the SC HoC amplifier cells 20 of main amplifier circuit 34 and peak amplifier circuit 36 may have an identical structure. The skilled person having benefit from the present disclosure will appreciate that beside 2-stacked SC HoC (M=2) architectures also M-stacked SC HoC with M>2 are possible. FIG. 3 suggests M=3, for example. Further, while in principle an identical number of SC HoC amplifier cells 20 may be used in main amplifier circuit 34 and peak amplifier circuit 36, e.g., N₁=N₂=N/2, implementations with different numbers of SC HoC amplifier cells in main amplifier circuit 34 and peak amplifier circuit 36 may be conceivable for certain applications. In the example shown in FIG. 3, the main amplifier circuit comprises N/2 SC HoC amplifier cells 20 coupled in parallel between the input 31 of the main amplifier circuit 34 and the common load 38. The peak amplifier circuit 36 also comprises N/2 SC HoC amplifier cells 20 coupled in parallel between the input 35 of the peak amplifier circuit 36 and the common load 38. N denotes an even integer, with N≥4. For example, N=8. In the latter case, the main amplifier circuit 34 and the peak amplifier circuit 36 may each comprise N₁=N₂=4 SC HoC amplifier cells 20.

The output 33 of the main amplifier circuit 34 and the output 37 of the peak amplifier circuit 36 may be coupled to the common load 38 via the transformer balun 32. The basic principle of operation of amplifier circuit 30 may be as follows: at low power, the peak amplifier circuit 36 is OFF providing a short circuit at the right side of the primary of balun 32. Under this condition, the main amplifier circuit 34 sees the load impedance R_{load} and saturates at 6-dB back-off. The peak amplifier circuit 36 may then be turned on, driving the balun 32 in antiphase (180°) relative to the main amplifier circuit 34 and giving V_{load}=Vₘₐᵢₙ+Vₚₑₐₖ (where V_{load}, Vₘₐᵢₙ, and Vₚₑₐₖ are voltage amplitudes for load, main, and peaking PAs), as well as increasing the current through the main amplifier circuit 34. Thus, the peak amplifier circuit 36 is configured to generate an antiphase output voltage relative to the main amplifier circuit 34. While the current provided by the main amplifier circuit 34 increases due to the peak amplifier circuit 36, the voltage the main amplifier circuit 34 presents to the balun 32 does not increase, so the impedance seen by the main amplifier circuit 34 decreases as Rₘₐᵢₙ=R_{load}/(1+Vₚₑₐₖ/Vₘₐᵢₙ). This allows the main amplifier circuit 34 to provide more power to load 38 while remaining in saturation.

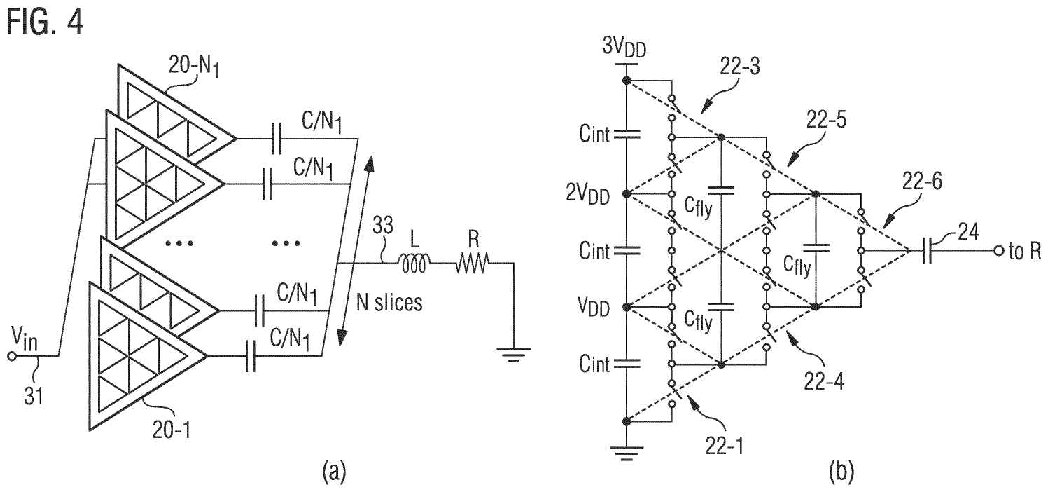

As mentioned before, also M-stacked SC HoC amplifier cells 20 with M>2 may be used in embodiments of the present disclosure. FIG. 4 illustrates an example of SC HoC amplifier cells 20 with M=3.

FIG. 4a shows a main amplifier circuit 34 comprising N₁ (=N/2) main SC HoC amplifier cells 20-1, 20-2, . . . , 20-N₁ coupled in parallel between input 31 and output 33 of the main amplifier circuit 34. As shown in FIG. 4b, each of the N₁ SC HoC amplifier cells 20 may have a 3-stacked SC HoC (M=3) architecture. That is, each SC HoC amplifier cell 20 may comprise a first CMOS inverter 22-1 coupled between V_{DD} and ground potential (e.g., source terminal of PMOS transistor of first CMOS inverter 22-1 may be coupled to V_{DD} while source terminal of NMOS transistor of first CMOS inverter unit 22-1 may be coupled to ground, or vice versa). A first control voltage Vᵢₙ₁ may be coupled to the gates of the P- and NMOS transistors of the first CMOS inverter 22-1. Further, a first capacitor Cᵢₙₜ may be coupled between V_{DD} and ground potential and hence between the source terminals of the P- and NMOS transistors of the first CMOS inverter 22-1. A second CMOS inverter 22-2 may be stacked on top of first CMOS inverter 22-1. In other words, second CMOS inverter 22-2 may be coupled in series to first CMOS inverter unit 22-1 (e.g., source terminal of PMOS transistor of first CMOS inverter 22-1 may be coupled to source terminal of NMOS transistor of second CMOS inverter 22-2). Thus, second CMOS inverter 22-2 may be coupled between 2V_{DD} and V_{DD}. A second control voltage Vᵢₙ₂ may be coupled to the gates of the P- and NMOS transistors of the second CMOS inverter 22-2. Further, a second capacitor Cᵢₙₜ may be coupled between 2V_{DD} and V_{DD} and hence between the source terminals of the P- and NMOS transistors of the second CMOS inverter 22-2. A third CMOS inverter 22-3 may be stacked on top of second CMOS inverter 22-2. In other words, third CMOS inverter 22-3 may be coupled in series to second CMOS inverter 22-2 (e.g., source terminal of PMOS transistor of second CMOS inverter 22-2 may be coupled to source terminal of NMOS transistor of third CMOS inverter unit 22-3). Thus, third CMOS inverter 22-3 may be coupled between 3V_{DD} and 2V_{DD}. A third control voltage Vᵢₙ₃ may be coupled to the gates of the P- and NMOS transistors of the third CMOS inverter 22-3. A fourth CMOS inverter 22-4 may be coupled between the outputs of the second and first CMOS inverters 22-2, 22-1. The intermediate V_{DD} node or a fourth control voltage Vᵢₙ₄ may be coupled to the gates of the P- and NMOS transistors of the fourth CMOS inverter 22-4. A fourth (flying) capacitor C_{fly} may be coupled between the outputs of the second and first CMOS inverters 22-2, 22-1 and hence between the source terminals of the P- and NMOS transistors of the fourth CMOS inverter 22-4. A fifth CMOS inverter 22-5 may be stacked on top of fourth CMOS inverter 22-4. Thus, fifth CMOS inverter 22-5 may be coupled between the outputs of the third and second CMOS inverters 22-3, 22-2. The intermediate 2V_{DD} node or a fifth control voltage Vᵢₙ₅ may be coupled to the gates of the P- and NMOS transistors of the fifth CMOS inverter 22-5. A fifth (flying) capacitor C_{fly} may be coupled between the outputs of the third and second CMOS inverters 22-3, 22-2 and hence between the source terminals of the P- and NMOS transistors of the fifth CMOS inverter 22-4. A final sixth CMOS inverter 22-6 may be coupled between the outputs of the fifth and fourth CMOS inverters 22-5, 22-4. The intermediate node between the fifth and fourth CMOS inverters 22-5, 22-4 or a sixth control voltage Vᵢₙ₆ may be coupled to the gates of the P- and NMOS transistors of the sixth CMOS inverter 22-6. A sixth (flying) capacitor C_{fly} may be coupled between the outputs of the fifth and fourth CMOS inverters 22-5, 22-2 and hence between the source terminals of the P- and NMOS transistors of the sixth CMOS inverter 22-6. The output of sixth CMOS inverter 22-6 may be coupled to a (switched) capacitor 24. Capacitor 24 may be coupled between load 38 and the SC HoC amplifier cell 20.

The 3-stacked SC HoC amplifier cell 20 of FIG. 4 may have three operation modes, leading to three different discrete output voltage levels. Control circuitry (not shown) may be configured to control an output voltage of the main amplifier circuit 34 by controlling respective output voltage levels of the first SC HoC amplifier cells and/or control an output voltage of the peak amplifier circuit 36 by controlling respective output voltage levels of the second SC HoC amplifier cells. The control circuitry may be configured to generate, based on amplitude and/or phase modulation signals of a transmitter circuit, first (or main) control signals for driving input gates of inverter units 22 of the first SC HoC amplifier cells 20 of the main amplifier circuit 34, and second (or peak) control signals for driving input gates of inverter units 22 of the second SC HoC amplifier cells 20 of the peak amplifier circuit 36.

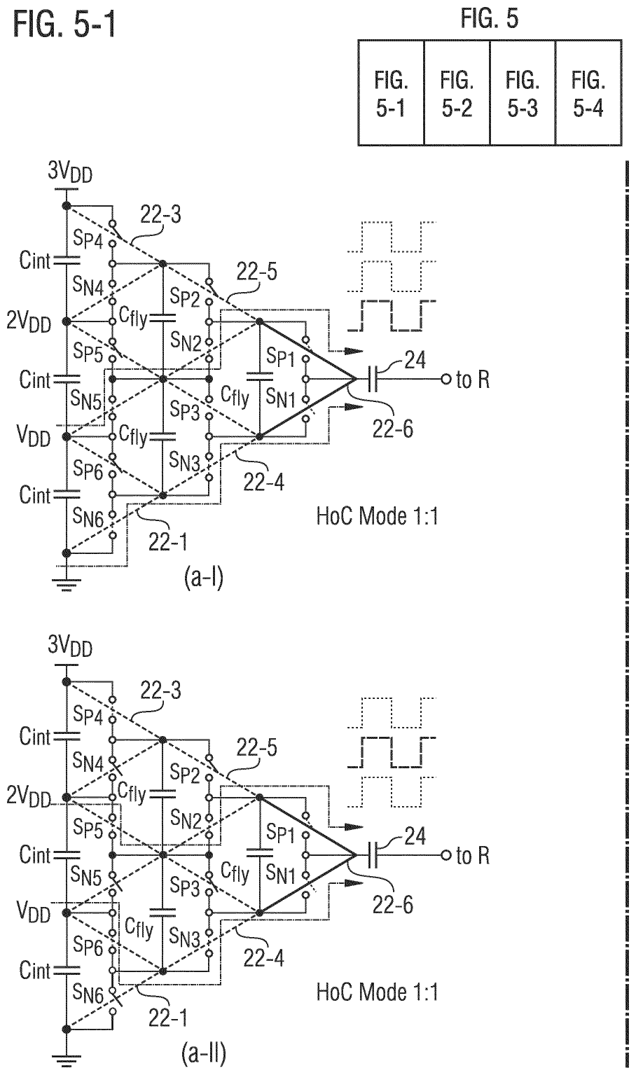

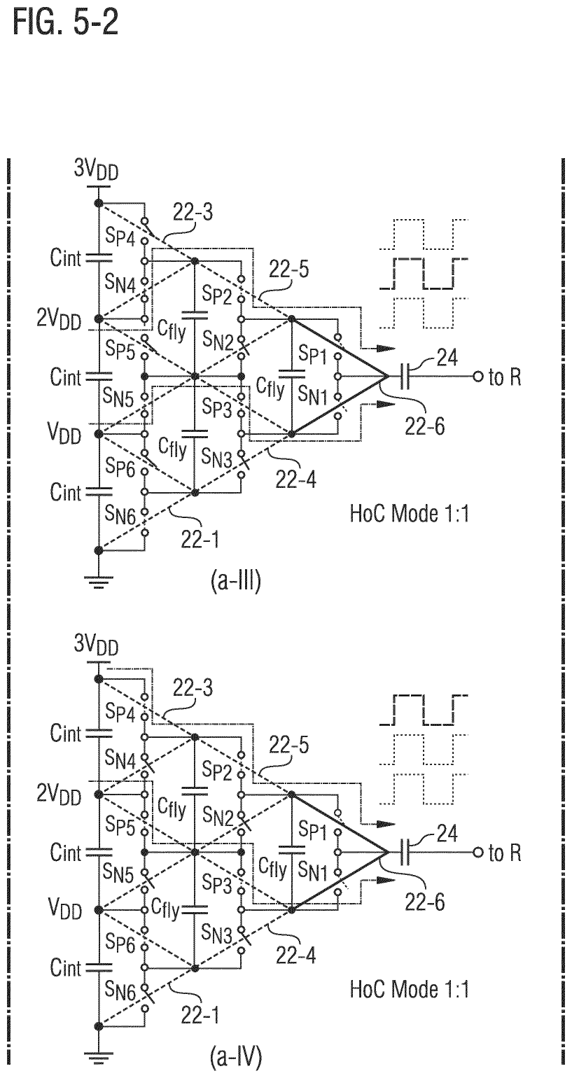

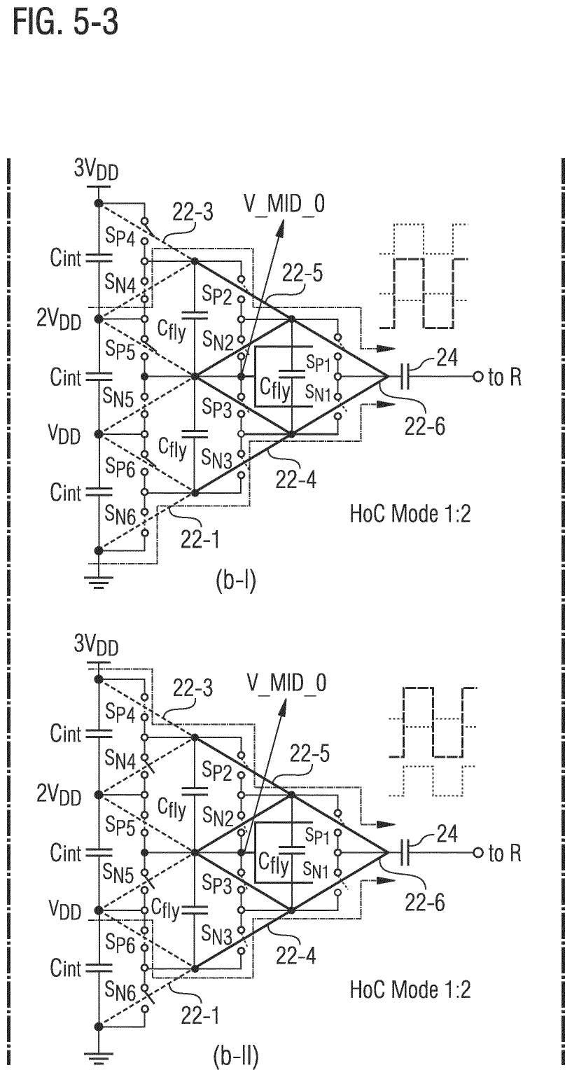

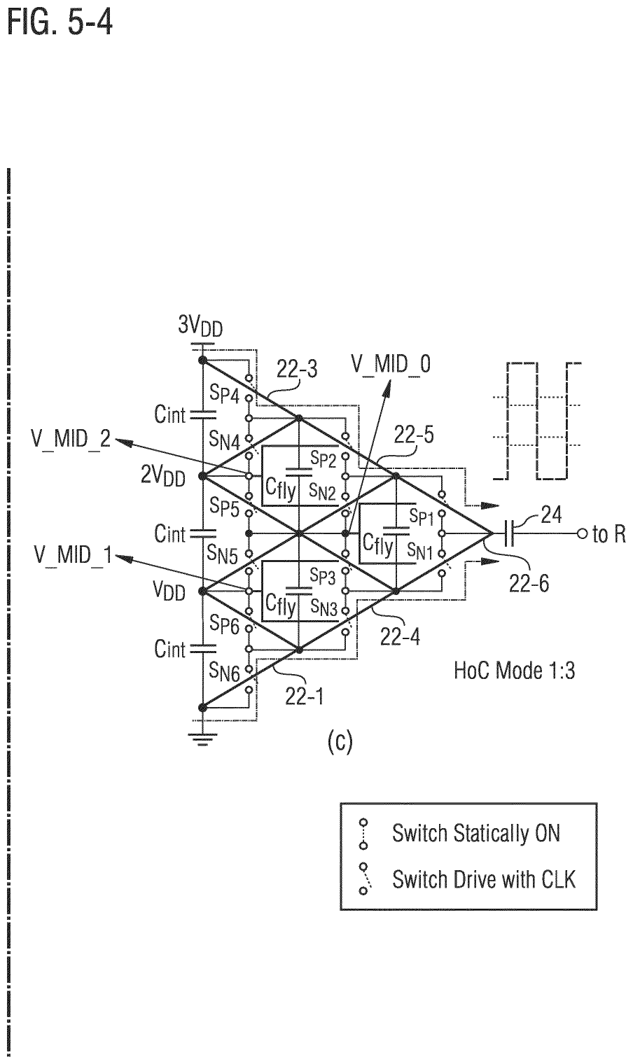

Different operation modes of each of the 3-stacked SC HoC amplifier cells 20 are illustrated in FIG. 5.

First, at SC HoC mode 1:1 (see FIGS. 5a-I-5a-IV), the tip (final CMOS inverter 22-6) of a SC HoC amplifier cell 20 may be driven by a phase-modulated (PM) local oscillator (LO) clock of a polar DTX, for example. The rest of the switches (P- and NMOS transistors) may be statically connected to high or low voltage levels. Therefore, the output voltage swing on the switched capacitor is V_{DD}. There are four different (capacitor) charging paths for this 1:1 mode, leading to V_{DD} voltage swing on the output switched capacitors 24. For example, in FIG. 5a-I, switches S_{P1} and S_{N1} (of final CMOS inverter 22-6) are connected to the LO clock, switches S_{P2} to S_{P6} (of PMOS transistors of CMOS inverters 22-1 to 22-5) are opened while switches S_{N2} to S_{N6} (of NMOS transistors of CMOS inverters 22-1 to 22-5) are closed. Thus, the supply voltages or charging/discharging paths of switches S_{P1} and S_{N1} (of final CMOS inverter 22-6) are between ‘GND’ and V_{DD}. Similar principles may be applied to the other charging paths in FIG. 5a-II, such as switches S_{P2}, S_{P3} (PMOS transistors of CMOS inverters 22-5 and 22-4) and switches S_{N4}, S_{N5}, S_{N6} (NMOS transistors of CMOS inverters 22-3, 22-2, 22-1) are opened while switches S_{N2}, S_{N3} (NMOS transistors of CMOS inverters 22-5 and 22-4) and switches S_{P4}, S_{P5}, S_{P6} (PMOS transistors of CMOS inverters 22-3, 22-2, 22-1) are closed. Consequently, the supply voltages of switches S_{P1} and S_{N1} (of CMOS inverter 22-6) are 2V_{DD} and V_{DD} respectively. FIG. 5a-III and 5a-IV illustrate two other possible charging/discharging paths which can also deliver V_{DD} voltage swing on the output switched capacitor 24.

Second, at SC HoC mode 1:2, the switches S_{P2}, S_{P3}, S_{N2}, S_{N3} in the middle column (CMOS inverters 22-4, 22-5) may be driven by the PM LO clock with respect to their own voltage domain (i.e., V_{DD}, 2V_{DD}, 3V_{DD}). The middle node of the middle column (i.e., V_MID_0) is the gate drive for the switches in the following stage (i.e., switch S_{P1} and S_{N1} of CMOS inverter 22-6). This connection is plotted in FIG. 5b-I and 5b-II as the bold wire. The rest of the switches may be statically connected to the high or low voltage levels within their own voltage domain. In FIG. 5b-I, switches S_{P4}, S_{P5}, S_{P6} (PMOS transistors of CMOS inverters 22-3, 22-2, 22-1) are opened while switches S_{N4}, S_{N5}, S_{N6} (NMOS transistors of CMOS inverters 22-3, 22-2, 22-1) are closed. The middle node V_MID_0 between switches S_{P3} and S_{N2} is the control level of switches S_{P1} and S_{N1} (of CMOS inverter 22-6). Therefore, the output voltage on switched capacitor 24 is either GND or 2V_{DD} In FIG. 5b-II, switches S_{N4}, S_{N5}, S_{N6} (NMOS transistors of CMOS inverters 22-3, 22-2, 22-1) are opened while switches S_{P4}, S_{P5}, S_{P6} (PMOS transistors of CMOS inverters 22-3, 22-2, 22-1) are closed. Hence, the output voltage on switched capacitor 24 is either V_{DD} or 3V_{DD}.

Finally, the SC HoC mode 1:3 has a similar operation as the HoC mode 1:2. In this context, six switches, i.e., S_{P4}, S_{P5}, S_{P6}, S_{N4}, S_{N5}, S_{N6} (PMOS and NMOS transistors of CMOS inverters 22-3, 22-2, 22-1) may be driven by the PM LO clock, while the rest of switches are driven by the respective middle node of preceding columns (i.e., V_MID_0, V_MID_1, V_MID_2). This connection is plotted in FIG. 5c as the bold wire. Subsequently, the output voltage swing on switched capacitor 24 is 3V_{DD}.

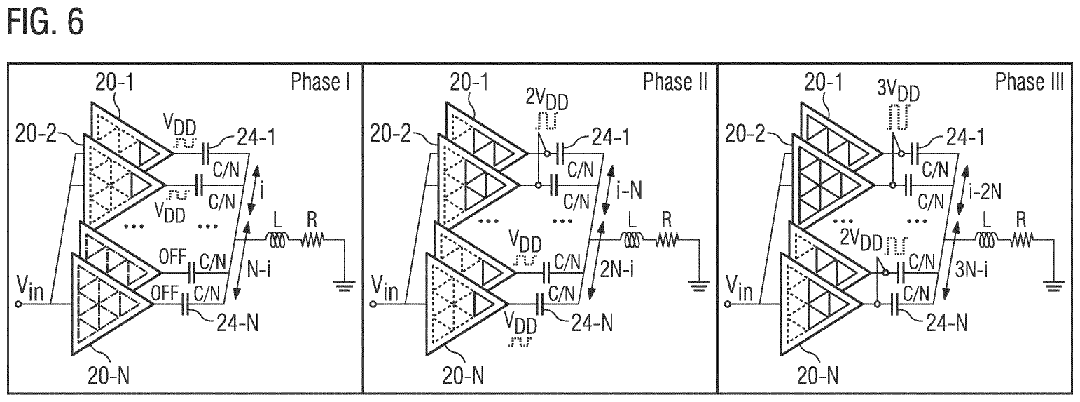

In summary, the example 3-stacked HoC SCPA (main amplifier circuit 34 or peak amplifier circuit 36) may have three modes of operation, which are illustrated in FIG. 6. Explanations are as follows:
a) When 0≤i≤N, i out of N SC HoC amplifier cells 20 of the SC amplifier circuit 34, 36 are in 1:1 mode, thus, the related switched capacitors 24 are connected to V_{DD}. It is worth mentioning that in order to have a balanced charging path, N SC HoC amplifier cells 20 may be equally divided into four parts so that each part in 1:1 HoC operation has the charging path as indicated in FIG. 5 a-I, II, III, and IV. Thus, each amplifier circuit 34, 36 may comprise an integer multiple of four SC HoC amplifier cells 20.
b) When N<i≤2N, i−N out of N SC HoC amplifier cells 20 of the amplifier circuit 34, 36 are in 1:2 mode, thus, the corresponding switched capacitors 24 are connected to 2V_{DD}. Similarly, 2N−i out of N SC HoC amplifier cells 20 of the amplifier circuit 34, 36 are in 1:1 mode, hence, the associated switched capacitors are connected to voltage swing of V_{DD}. Again, to meet balanced charging/discharging paths in HoC 1:2 mode, N SC HoC amplifier cells may be divided into two parts equally that have two different charging paths as in FIG. 5b-I and II.
c) When 2N<i≤3N, i−2N out of N SC HoC amplifier cells 20 of the amplifier circuit 34, 36 are in 1:3 mode, accordingly, the related switched capacitors 24 are connected to 3V_{DD}. Likewise, 3N−i out of N SC HoC amplifier cells 20 of the HoC PAs 34, 36 are in 1:2 mode, consequently, the corresponding switched capacitors 24 are connected to 2V_{DD}.

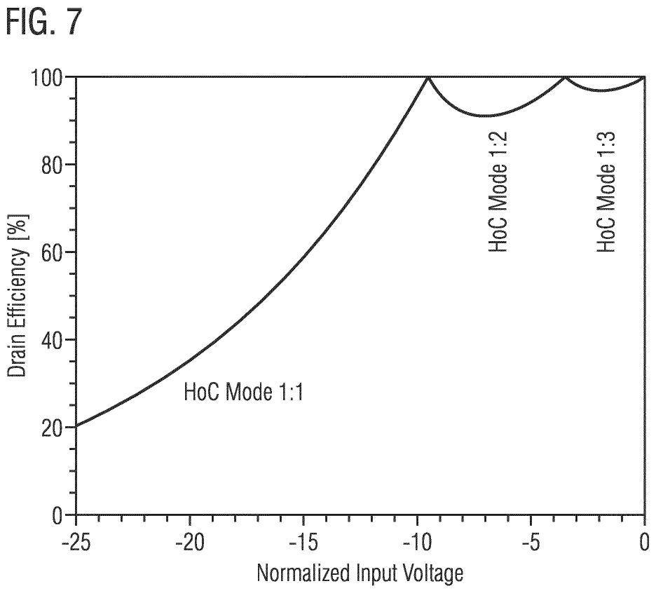

Doing so, a HoC SC amplifier circuit 34, 36 may generate three efficiency peaks over a 9.54 dB PBO region. FIG. 7 shows an efficiency plot of a proposed 3-stacked HoC SC amplifier circuit 34, 36. Efficiency peaks of this 3-way HoC amplifier circuit 34, 36 are at −9.54 dB, −3.5 dB and 0 dB PBO, respectively. These values also mark switching points between the different modes of operation. The skilled person having benefit from the present disclosure will appreciate that the proposed DTX could be extended by introducing more HoC modes of operation to further enhance the system efficiency at PBO and deliver more than 23 dBm peak output power exploiting nanoscale baseline CMOS. However, only increasing HoC PA's voltage swing by deploying more stacked CMOS power cells 20 may not always be practical solution, because any semiconductor technology has certain supported voltage range.

Turning back to FIG. 3, the presented M-stacked HoC architecture of FIG. 4 to 7 can be combined with a voltage-mode Doherty (VMD) concept to a novel DTX architecture: M-stacked HoC-VMD SCPA 30. A fundamental idea of the present disclosure is to construct two sets of M-stacked HoC PAs (main amplifier circuit 34 and peak amplifier circuit 36) operating as a voltage mode Doherty power amplifier. FIG. 3 shows the concept of an example 3-stacked HoC-VMD SCPA in a single-ended configuration.

The proposed Doherty amplifier circuit 30 may comprise N SC HoC amplifier cells 20. As depicted, the proposed Doherty amplifier circuit 30 left half-section (N/2 HoC amplifier cells) features as the ‘Main’ power amplifier 34, and its right half counterpart (the remaining N/2 SC HoC amplifier cells) acts as the ‘Peak’ power amplifier 36. Each half-section 34, 36 may operate as a 3-stacked HoC power amplifier. As mentioned above, more or less HoC amplifier stacks may be employed. It is worth mentioning, that there may be two possible operation sequences to drive the proposed Doherty amplifier circuit 30, namely HoC-VMD-HoC mode and VMD-HoC-VMD mode. First, VMD-HoC-VMD mode (also denoted as ‘Mode A’ in the following) will be described.

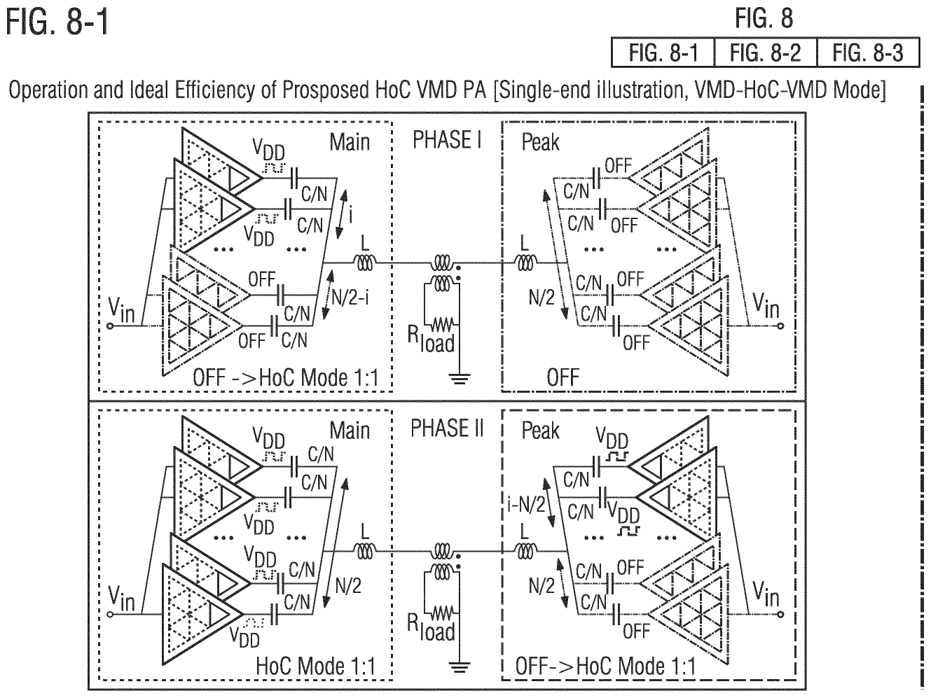

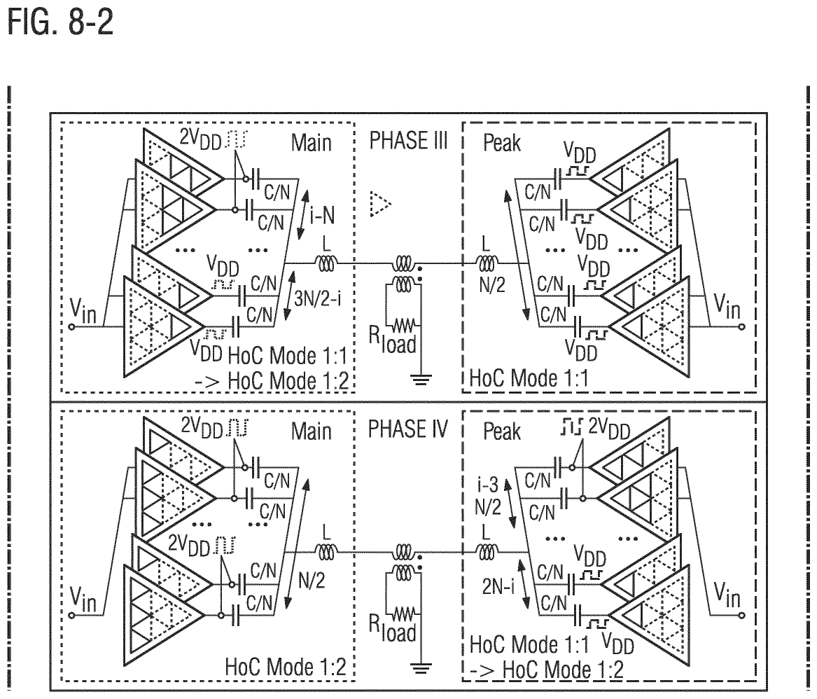

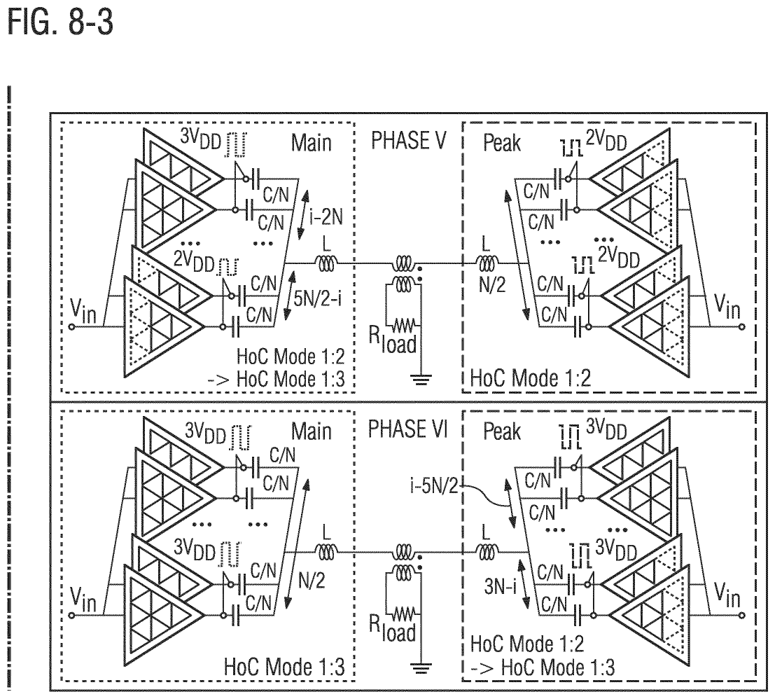

Assume that i out of N amplifier cells 20 are turned on for a specific input envelope (amplitude modulated (AM)) code. The different amplifier operation phases are shown in FIG. 8:
a) Phase I: when

$$0 \leq i \leq \frac{N}{2} ,$$

i out of N/2 amplifier cells 20 in ‘Main’ PA 34 turn on featuring as the HoC 1:1 mode. In this context, its ‘Peak’ PA 36 is fully off. As i increases and becomes equal to N/2, all SC HoC amplifier cells 20 in the ‘Main’ PA 34 deliver V_{DD} voltage swing to the associated switched capacitors 24. Thus, in a first operation mode (phase I), one or more SC HoC amplifier cells 20 of the main amplifier circuit 34 may be configured to generate a first output voltage swing (V_{DD}) while the SC HoC amplifier stages 20 of the peak amplifier circuit 36 are off.
b) Phase II: when

$$\frac{N}{2} < i \leq N , i - \frac{N}{2}$$

out of N/2 amplifier cells 20 in the ‘Peak’ PA 36 turn on operating as the HoC 1:1 mode while N/2 amplifier cells 20 of ‘Main’ PA 34 remain in the HoC 1:1 mode. As i increases and becomes equal to N, all PAs in the ‘Main’ 34 and ‘Peak’ 34 deliver V_{DD} voltage swing to the related switched capacitors 24. Thus, in a second operation mode (phase II) subsequent to first operation mode, all SC HoC amplifier cells 20 of the main amplifier circuit 34 may be configured to generate the first output voltage swing (V_{DD}) and one or more SC HoC amplifier cells 20 of the peak amplifier circuit 36 may be configured to generate the first output voltage swing (V_{DD}).
c) Phase III: when

$$N < i \leq \frac{3 N}{2} ,$$

i−N out of N/2 amplifier cells 20 in the ‘main’ PA 34 switch from HoC 1:1 to HoC 1:2 mode while N/2 amplifier cells 20 of ‘peak’ DPA 36 remain in HoC 1:1 mode. As i increases and becomes equal to 3N/2, all PAs in ‘main’ DPA 34 deliver 2V_{DD} voltage swing and ‘peak’ deliver V_{DD} voltage swing to the corresponding switched capacitors 24. Thus, in a third operation mode (phase III) subsequent to second operation mode, one or more SC HoC amplifier cells 20 of the main amplifier circuit 34 may be configured to generate a second output voltage swing (2V_{DD}) larger than the first output voltage swing (V_{DD}) and all SC HoC amplifier cells 20 of the peak amplifier circuit 36 may be configured to generate the first output voltage swing (V_{DD}).
d) Phase IV: when

$$\frac{3 N}{2} < i \leq 2 N , i - \frac{3 N}{2}$$

out of N/2 amplifier cells 20 in the ‘peak’ PA 36 switch from HoC 1:1 to HoC 1:2 mode, while N/2 amplifier cells 20 of the ‘main’ DPA 34 remain in HoC 1:2 mode. As i increases and becomes equal to 2N, all power cells in the ‘Main’ and ‘Peak’ DPAs deliver 2V_{DD} voltage swing to the related switched capacitors 24. Thus, in a fourth operation mode (phase IV) subsequent to third operation mode, all SC HoC amplifier cells 20 of the main amplifier circuit 34 may be configured to generate the second output voltage swing (2V_{DD}) and one or more SC HoC amplifier cells 20 of the peak amplifier circuit 36 may be configured to generate the second output voltage swing (2V_{DD}).
e) Phase V: when

$$2 N < i \leq \frac{5 N}{2} ,$$

i−2N out of N/2 amplifier cells 20 in the ‘main’ PA 34 switch from HoC 1:2 to HoC 1:3 mode, while N/2 amplifier cells 20 of the ‘peak’ DPA 36 remain in HoC 1:2 mode. As i increases and becomes equal to 5N/2, all PAs 20 in ‘main’ DPA 34 deliver 3V_{DD} voltage swing and ‘peak’ deliver 2V_{DD} voltage swing to the associated switched capacitors 24. Thus, in a fifth operation mode (phase V) subsequent to fourth operation mode, where one or more SC HoC amplifier cells 20 of the main amplifier circuit 34 may be configured to generate a third output voltage swing (3V_{DD}) larger than the second output voltage swing (2V_{DD}) and all SC HoC amplifier cells 20 of the peak amplifier circuit 34 may be configured to generate the second output voltage swing (2V_{DD}).
f) Phase VI: when

$$\frac{5 N}{2} < i \leq 3 N , i - \frac{5 N}{2}$$

out of N/2 amplifier cells 20 in the ‘peak’ PA 36 switch from HoC 1:2 to HoC 1:3 mode, while N/2 amplifier cells 20 of the ‘main’ DPA 34 remain in HoC 1:3 mode. As i increases and becomes equal to 3N, all PAs 20 in ‘main’ and ‘peak’ DPAs deliver 3V_{DD} voltage swing to the corresponding switched capacitors 24. Thus, in a sixth operation mode (phase VI) subsequent to fifth operation mode, all SC HoC amplifier cells 20 of the main amplifier circuit 34 may be configured to generate the third output voltage swing (3V_{DD}) and one or more SC HoC amplifier cells 20 of the peak amplifier circuit 36 may be configured to generate the third output voltage swing (3V_{DD}).

The skilled person having benefit from the present disclosure will appreciate that phases I-IV are also possible with a 2-stacked HoC power amplifier setup and even more phases (operation modes) could be implemented with M>3. Also, different voltage swings are possible depending on the supply voltage levels. For example, the different voltage swings may correspond to different fractions of supply voltage V_{DD} (e.g., V_{DD}/3, V_{DD}/2, V_{DD}).

Thus, control circuitry controlling the proposed Doherty amplifier circuit 30 may be configured to operate the amplifier circuit 30 in different operation modes. In a first operation mode, one or more SC HoC amplifier cells 20 of the main amplifier circuit 34 may be configured to generate a first output voltage swing while the SC HoC amplifier stages 20 of the peak amplifier circuit 36 are off. In a second operation mode (higher input voltage or less PBO than in first operation mode), all SC HoC amplifier cells 20 of the main amplifier circuit 34 may be configured to generate the first output voltage swing and one or more SC HoC amplifier cells 20 of the peak amplifier circuit 36 may be configured to generate the first output voltage swing. In a third operation mode (higher input voltage or less PBO than in second operation mode), one or more SC HoC amplifier cells 20 of the main amplifier circuit 34 may be configured to generate a second output voltage swing larger than the first output voltage swing and all SC HoC amplifier cells 20 of the peak amplifier circuit 36 may be configured to generate the first output voltage swing. In a fourth operation mode (higher input voltage or less PBO than in third operation mode), all SC HoC amplifier cells 20 of the main amplifier circuit 34 may be configured to generate the second output voltage swing and one or more SC HoC amplifier cells 20 of the peak amplifier circuit 36 may be configured to generate the second output voltage swing. For an M-stacked HoC power amplifier setup, with M>2, there may be a fifth operation mode (higher input voltage or less PBO than in fourth operation mode), where one or more SC HoC amplifier cells 20 of the main amplifier circuit 34 may be configured to generate a third output voltage swing larger than the second output voltage swing and all SC HoC amplifier cells 20 of the peak amplifier circuit 34 may be configured to generate the second output voltage swing. In a sixth operation mode (higher input voltage or less PBO than in fifth operation mode), all SC HoC amplifier cells 20 of the main amplifier circuit 34 may be configured to generate the third output voltage swing and one or more SC HoC amplifier cells 20 of the peak amplifier circuit 36 may be configured to generate the third output voltage swing.

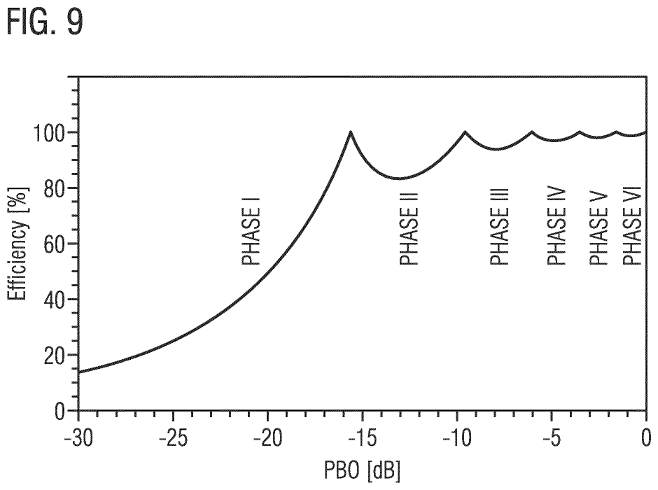

With the aforementioned operation, the proposed DPA architecture may show an ideal efficiency vs PBO characteristic as depicted in FIG. 9. The peak efficiency points occur at −15.6 dB, −9.54 dB, −6 dB, −3.5 dB, −1.58 dB PBO and 0 dB, hence at six different power levels. The first operation mode may be used until −15.6 dB, the second operation mode may be used from −15.6 dB until −9.54 dB, the third operation mode may be used from −9.54 dB until, −6 dB, the fourth operation mode may be used from −6 dB until −3.5 dB, the fifth operation mode may be used from −3.5 dB until −1.58 dB, and the sixth operation mode may be used from −1.58 dB until 0 dB.

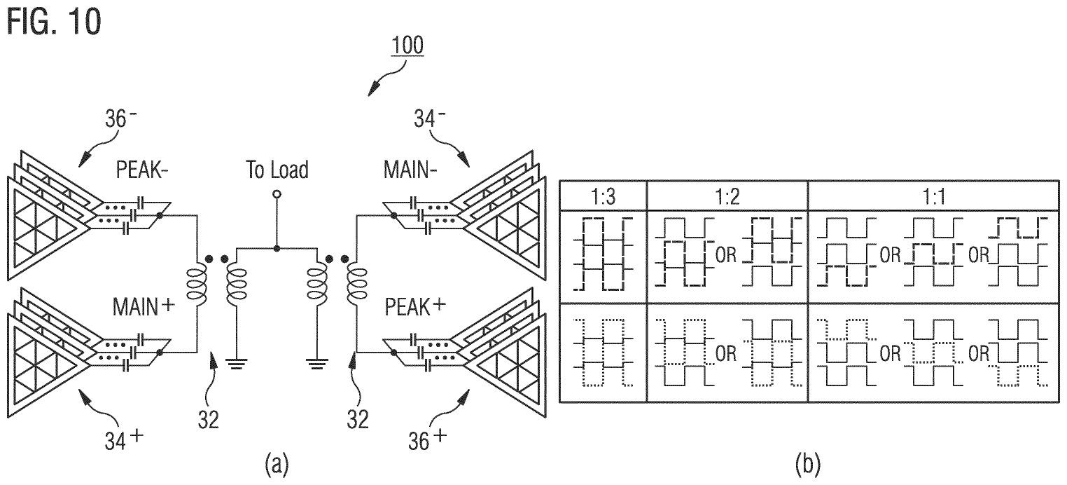

While FIG. 3 showed a single-ended implementation of amplifier circuit 30, embodiments of the present disclosure also encompass HoC-VMD SC power amplifier circuits in a push-pull configuration, as described in FIG. 10. A push-pull amplifier is a type of electronic circuit that uses a pair of active devices that alternately supply current to, or absorb current from, a connected load. This kind of amplifier can enhance both the load capacity and switching speed. Push-pull outputs are present in TTL and CMOS digital logic circuits and in some types of amplifiers, and are usually realized by a complementary pair of transistors, one dissipating or sinking current from the load to ground or a negative power supply, and the other supplying or sourcing current to the load from a positive power supply.

FIG. 10 shows an amplifier circuit 100 comprising a main push-pull amplifier circuit 34⁺, 34⁻ and a peak push-pull amplifier circuit 36⁺, 36⁻. An output of a sourcing portion 34⁺ of main push-pull amplifier is coupled to an output of a sinking portion 36⁻ of peak push-pull amplifier via a primary side of a first balun 32 (left). An output of a sinking portion 34⁻ of main push-pull amplifier is coupled to an output of a sourcing portion 36⁺ of peak push-pull amplifier via a primary side of a second balun 32 (right). The secondary sides of the baluns 32 are coupled to a common load. The sourcing portion 34⁺ of main push-pull amplifier comprises a plurality of SC HoC amplifier cells 20 coupled in parallel between an input and an output of the sourcing portion 34⁺. The sinking portion 34⁻ of main push-pull amplifier comprises a plurality of SC HoC amplifier cells 20 coupled in parallel between an input and an output of the sinking portion 34⁻. Sourcing portion 34⁺ and sinking portion 34⁻ operate antiphase (180°) each other. The sourcing portion 36⁺ of peak push-pull amplifier comprises a plurality of SC HoC amplifier cells 20 coupled in parallel between an input and an output of the sourcing portion 36⁺. The sinking portion 36⁻ of peak push-pull amplifier comprises a plurality of SC HoC amplifier cells 20 coupled in parallel between an input and an output of the sinking portion 36⁻. Sourcing portion 36⁺ and sinking portion 36⁻ operate antiphase to each other.

Every SC HoC amplifier cell 20 in each ‘main’ amplifier 34⁺, 34⁻ or ‘peak’ amplifier 36⁺, 36⁻ has its own designated waveform level in different operation modes so that the voltage swings on the switched capacitors 24 may be well balanced. The balanced DPA topology of FIG. 10 comprises four identical 3-stacked HoC SCPA, giving rise to a stable voltage on clamping capacitors, Cᵢₙₜ, in FIG. 3.

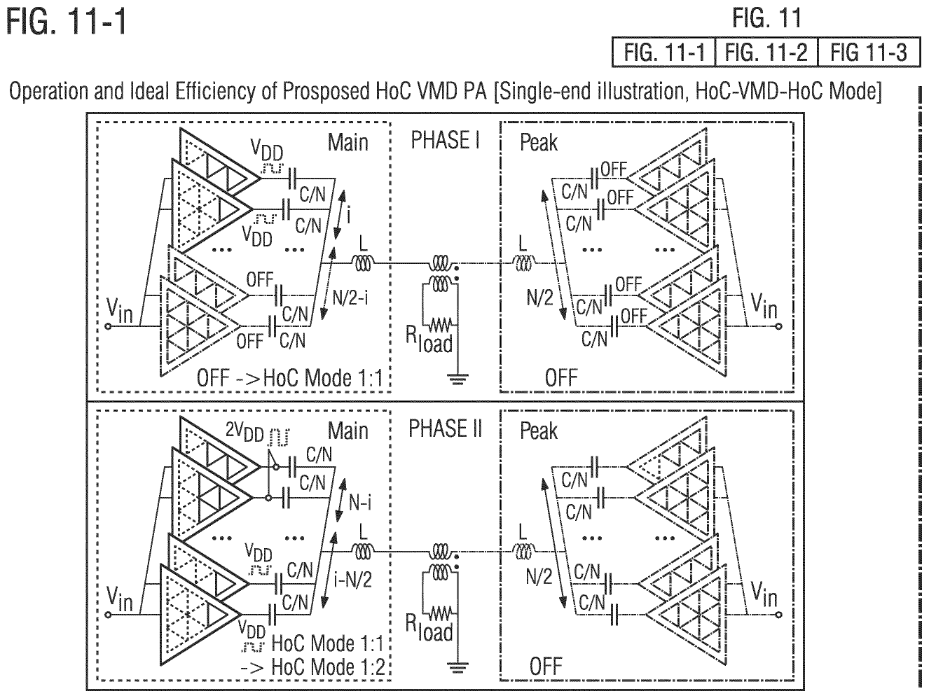

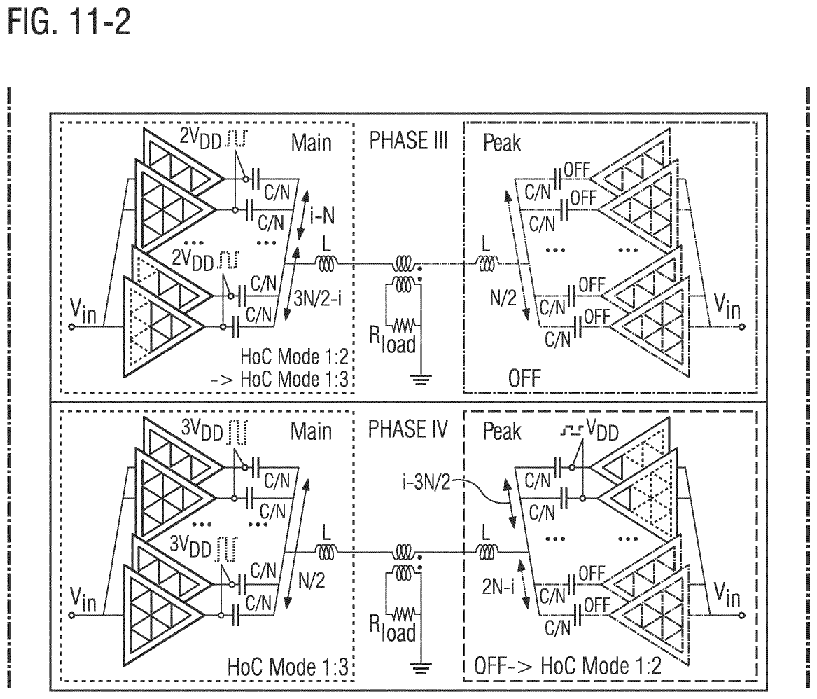

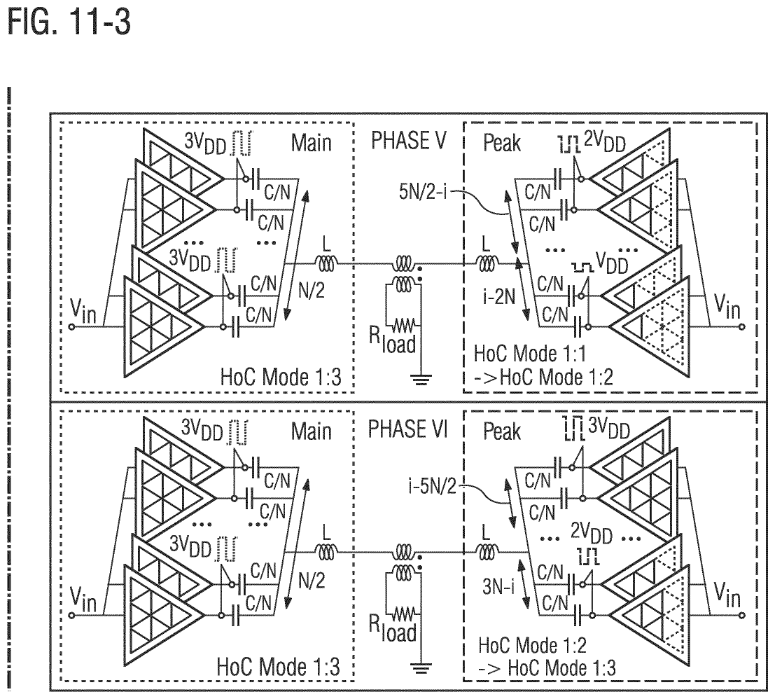

The operation sequence for 3-stacked HoC-VMD-HoC (also as ‘Mode B’ in the following) will be explained in a simplified manner referring to FIG. 11:

First, the ‘main’ amplifier 34 operates in HoC 1:1 mode (phase I), HoC 1:2 mode (phase II), and HoC 1:3 mode (phase III) sequentially. In this context, the ‘peak’ amplifier 36 is OFF. Next, the ‘main’ amplifier 34 remains at HoC 1:3 mode with the ‘peak’ amplifier 36 operates in HoC 1:1 mode (phase IV), HoC 1:2 mode (phase V), and HoC 1:3 mode (phase VI) sequentially. In this example, control circuitry may be configured to operate the amplifier circuit 30 in different operation modes. In a first operation mode (phase I), one or more SC HoC amplifier cells 20 of the main amplifier circuit 34 may be configured to generate a first output voltage swing (HoC 1:1 mode) while the SC HoC amplifier stages 20 of the peak amplifier circuit 36 are off. In a subsequent second operation mode (phase II) (higher input voltage or less PBO than in first operation mode), one or more SC HoC amplifier cells 20 of the main amplifier circuit 34 may be configured to generate a second output voltage swing (HoC 1:2 mode) larger than the first voltage output swing (HoC 1:1 mode) while the SC HoC amplifier cells of the peak amplifier circuit 36 are off. In a subsequent third operation mode (phase III) applicable to 3-stacked HoC SCPA (higher input voltage or less PBO than in second operation mode), one or more SC HoC amplifier cells 20 of the main amplifier circuit 34 may be configured to generate a third output voltage swing (HoC 1:3 mode) larger than the second output voltage swing (HoC 1:2 mode) while the SC HoC amplifier cells 20 of the peak amplifier circuit 36 are off. In a subsequent fourth operation mode (phase IV) (higher input voltage or less PBO than in third operation mode), all SC HoC amplifier cells 20 of the main amplifier circuit 36 may be configured to generate the third output voltage swing (HoC 1:3 mode) and one or more SC HoC amplifier cells 20 of the peak amplifier circuit 36 may be configured to generate the first output voltage swing (HoC 1:1 mode). In a subsequent fifth operation mode (phase V) (higher input voltage or less PBO than in fourth operation mode), all SC HoC amplifier cells 20 of the main amplifier circuit 36 may be configured to generate the third output voltage swing (HoC 1:3 mode) and one or more SC HoC amplifier cells 20 of the peak amplifier circuit 36 may be configured to generate the second output voltage swing (HoC 1:2 mode). In a subsequent sixth operation mode (phase VI) (higher input voltage or less PBO than in fifth operation mode), all SC HoC amplifier cells 20 of the main amplifier circuit 34 may be configured to generate the third output voltage swing (HoC 1:3 mode) and one or more SC HoC amplifier cells 20 of the peak amplifier circuit 36 may be configured to generate the third output voltage swing (HoC 1:3 mode). The skilled person having benefit from the present disclosure will appreciate that a 2-stacked HoC-VMD-HoC may only comprise phases I, II, VI, and V. Ideally, this operation demonstrates six efficiency peaks, as illustrated in FIG. 9.

To operate the proposed M-stacked HoC-VMD SCPA properly in a polar DTX configuration, control circuitry has to precisely generate AM-PM control signals for driving the input gates of each inverter 22 within each HoC amplifier cell 20 (for a 3-stacked design, there are 6 inverters 22 within one HoC amplifier cell 20). Thus, the amplifier circuit 30, 100 may comprise control circuitry which is configured to generate, based on amplitude and/or phase modulation signals of a transmitter circuit, first (main) control signals for driving input gates of inverter units 22 of the first (main) SC HoC amplifier cells 20 of main amplifier 34 and second (peak) control signals for driving input gates of inverter units 22 of the second (peak) SC HoC amplifier cells 20 of peak amplifier 36. The control circuitry may be configured to generate antiphase second (peak) control signals relative to the first (main) control signals. The (AM-PM) control signals may be obtained by mixing a PM LO clock signal with an AM input code signal of the proposed DTX.

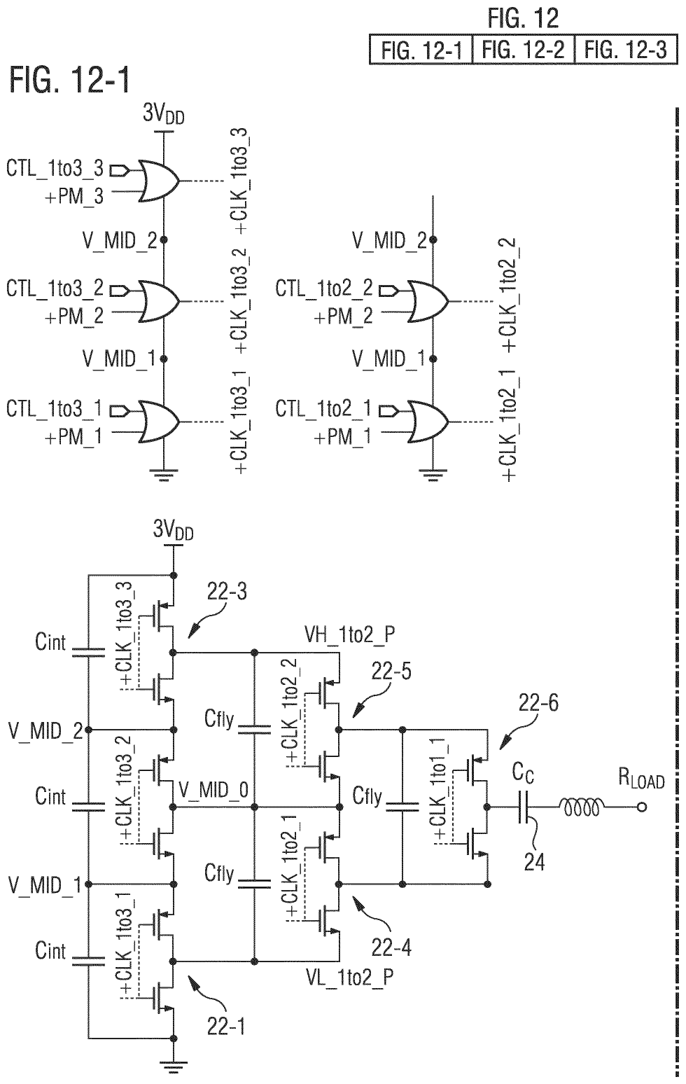

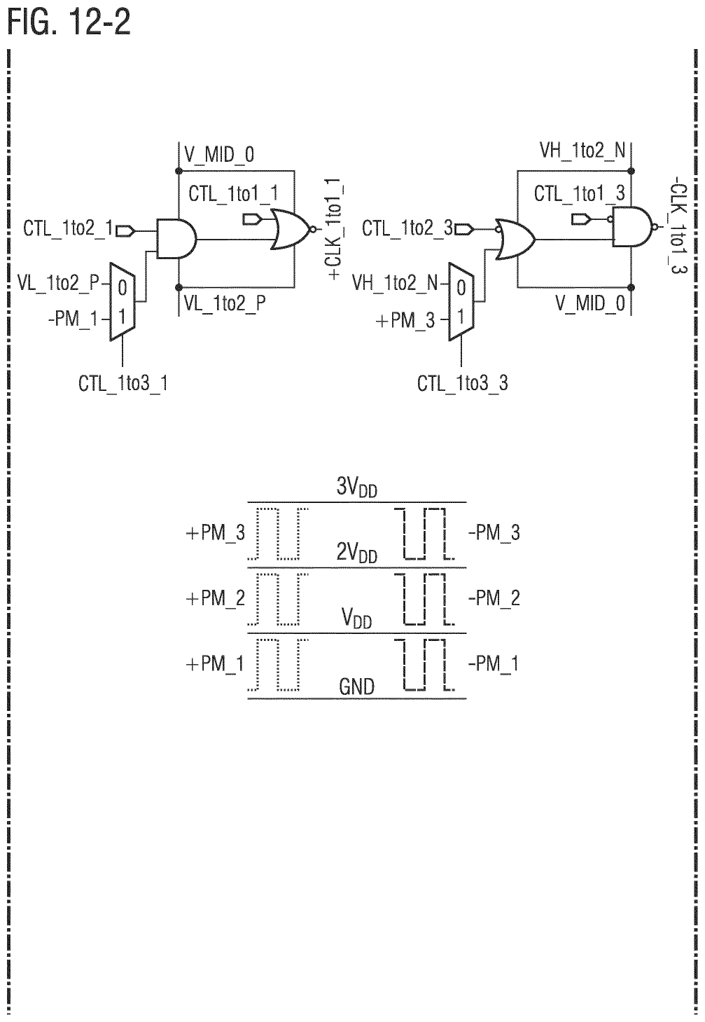

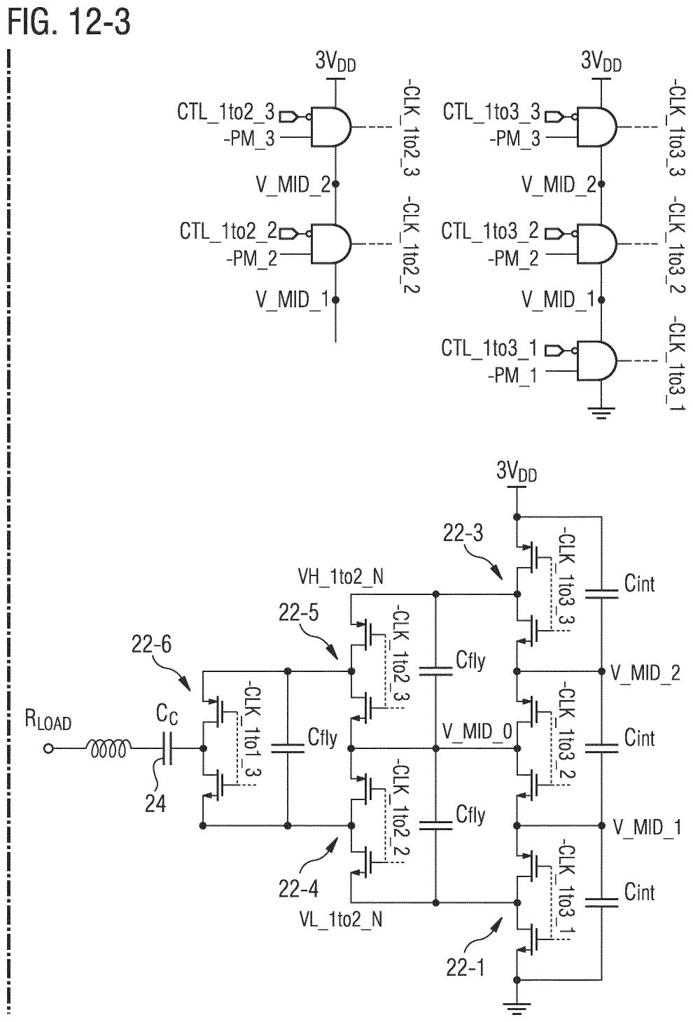

FIG. 12 shows an example of the mixing operation for the proposed 3-stacked HoC-VMD SCPA. The inputs of the logic gates in the figure CTL_1tox_x are the control signals, decoded from the operation modes (HoC 1:1 mode, HoC 1:2 mode, HoC 1:3 mode) and the PM_x is the LO clock in V_{DD}, 2V_{DD}, 3V_{DD} voltage domains.

The control signal +CLK_1to3_1 for the first inverter 22-1 of main SC HoC amplifier cell 20 may be derived from a logic OR combination of CTL_1to3_1 and +PM_1. The control signal +CLK_1to3_2 for the second inverter 22-2 of main SC HoC amplifier cell 20 may be derived from a logic OR combination of CTL_1to3_2 and +PM_2. The control signal +CLK_1to3_3 for the third inverter 22-3 of main SC HoC amplifier cell 20 may be derived from a logic OR combination of CTL_1to3_3 and +PM_3. The control signal +CLK_1to2_1 for the fourth inverter 22-4 of main SC HoC amplifier cell 20 may be derived from a logic OR combination of CTL_1to2_1 and +PM_1. The control signal +CLK_1to2_2 for the fifth inverter 22-5 of main SC HoC amplifier cell 20 may be derived from a logic OR combination of CTL_1to2_2 and +PM_2. The control signal +CLK_1to1_1 for the sixth inverter 22-6 of main SC HoC amplifier cell 20 may be derived from a logic OR combination of CTL_1to1_1 and a signal derived from a logic combination of CTL_1to2_1 and a demultiplexed signal including −PM_1. As can be seen from FIG. 12, the control signals for the inverters 22 of the peak SC HoC amplifier cell 20 (right) are essentially antiphase to the control signals for the inverters 22 of the main SC HoC amplifier cell 20 (left). The skilled person having benefit from the present disclosure will appreciate that the control signal generation may generally be different from the illustrated example and depend on the employed transmitter and modulation technique. Also, the control signal generation will be different for 2-stacked HoC-VMD SCPA. However, one can say that the control signals may be generated based on amplitude and/or phase modulation signals of a transmitter circuit.

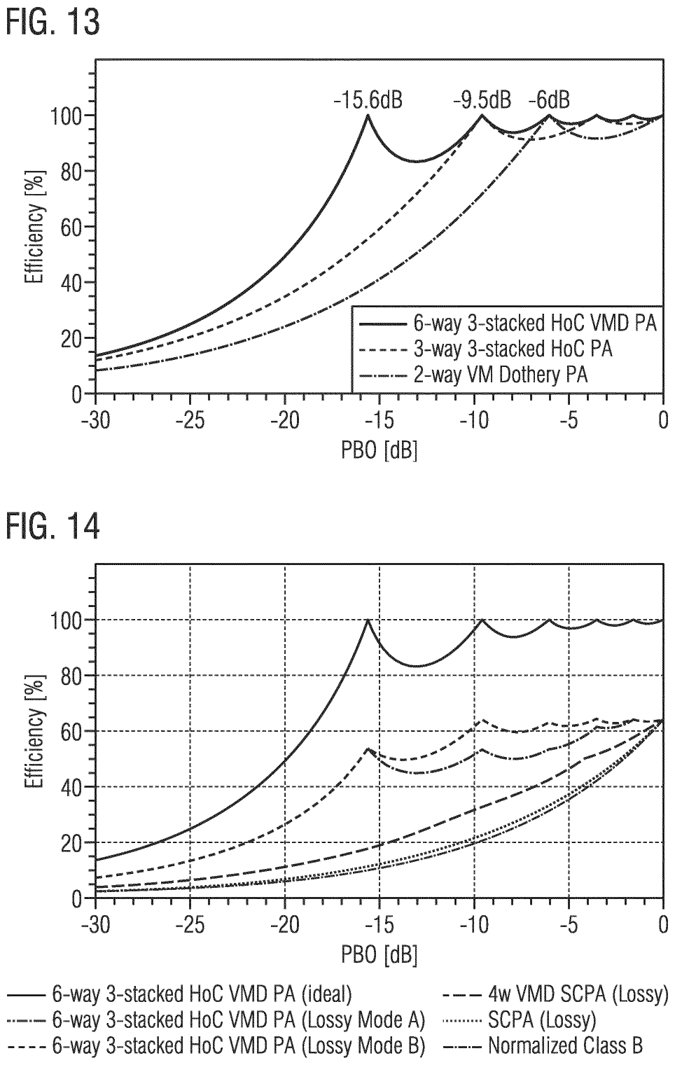

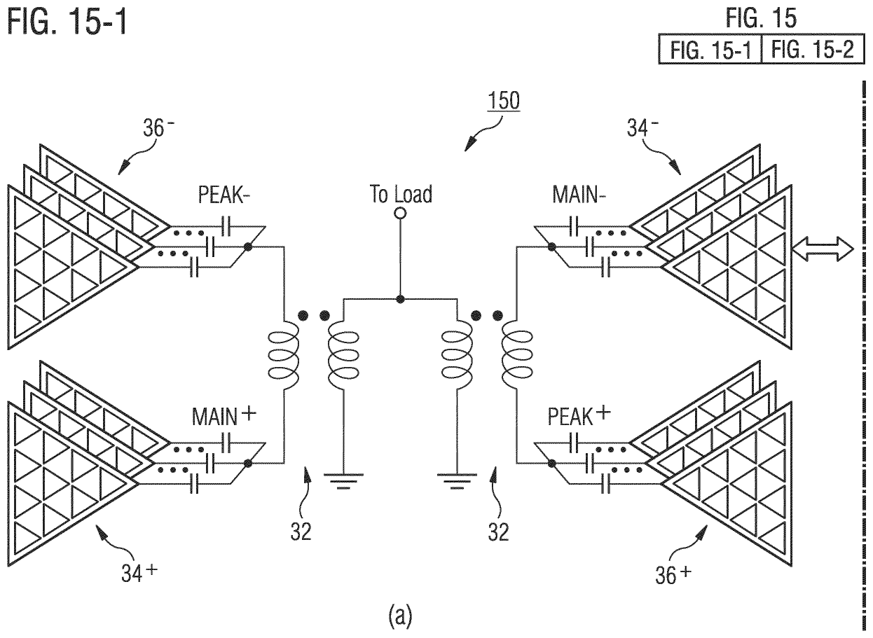

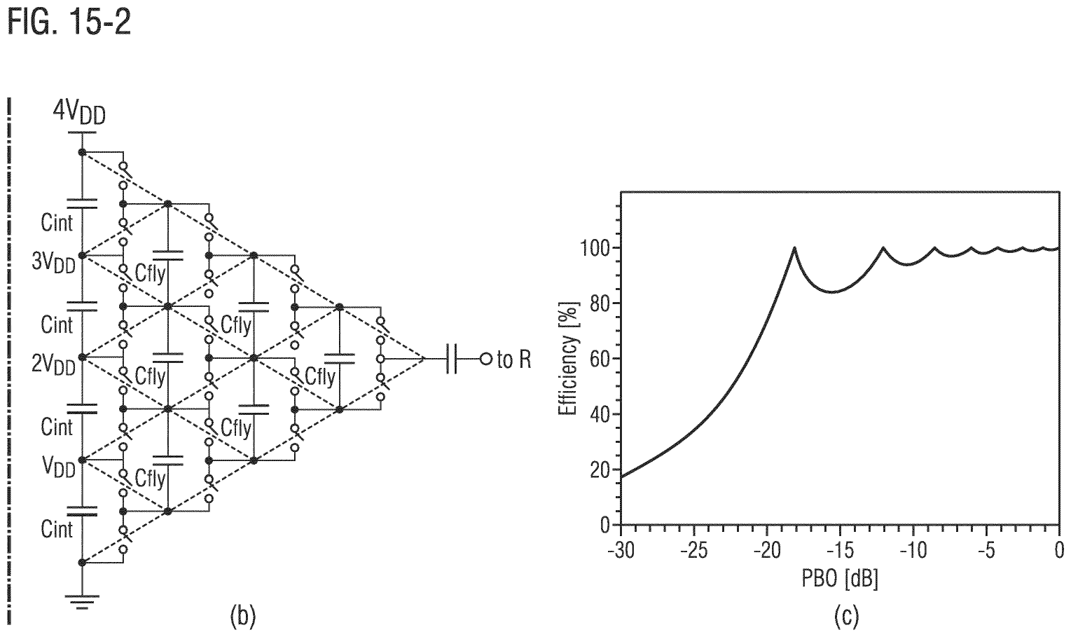

The architecture proposed herein may include the following advantages. First, as mentioned before, the efficiency at power back-off may be improved. Compared to state-of-the-art PA PBO efficiency enhancement structures, such as VMD PA, in a 3-stacked HoC-VMD SCPA configuration, the efficiency can be enhanced up to −15.6 dB PBO. FIG. 13 shows an ideal efficiency comparison between conventional 2-way, 3-way Doherty PA and the proposed PA. Second, in practical implementations, PAs always suffer from various losses, thus the efficiency would be decreased. This efficiency drop becomes more prominent in deep power back-off (PBO) regions. As can be observed in resent literatures, digital PAs involving switch-capacitor structures often have less efficiency boost unlike what they claimed in the theoretical analysis. However, the proposed amplifier structure shows less efficiency loss since the HoC structure is introduced which can compensate the drawbacks of switch-capacitor PA. FIG. 14 shows a comparison of different SCPA structures and typical Class B PA. For example, the 6-way HoC VMD PA has 2.9 times efficiency improvement in a lossy situation compared to the state-of-art 4-way VMD PA. Third, the frontend voltage swing of the proposed architecture can be easily scaled up with multi-level stacked CMOS switches. As depicted in FIG. 15, when the proposed architecture is scaled up to 4V_{DD} (i.e., M=4), its 18 dB PBO efficiency may be boosted.

Note that the present technology can also be configured as described below.

Example 1 is an amplifier circuit comprising a main amplifier circuit and at least one peak amplifier circuit. The main amplifier circuit comprises a plurality of first SC HoC, amplifier cells coupled in parallel between an input and an output of the main amplifier circuit. The peak amplifier circuit comprises a plurality of second SC HoC amplifier cells coupled in parallel between an input and an output of the peak amplifier circuit. The output of the main amplifier circuit and the output of the peak amplifier circuit are coupled to a common load.

In Example 2, each of the first and second SC HoC amplifier cells of Example 1 is configurable for different discrete output voltage levels or swings.

In Example 3, the peak amplifier circuit of any one of the previous Examples is configured to generate an antiphase output voltage relative to the main amplifier circuit.

In Example 4, the output of the main amplifier circuit and the output of the peak amplifier circuit of any one of the previous Examples are coupled to the common load via a transformer balun.

In Example 5, the main amplifier circuit of any one of the previous Examples comprises N/2 SC HoC amplifier cells coupled in parallel between the input of the main amplifier circuit and the common load, and the peak amplifier circuit of any one of the previous Examples comprises N/2 SC HoC amplifier cells coupled in parallel between the input of the peak amplifier circuit and the common load. N denotes an even integer.

In Example 6, N≥8.

In Example 7, each of the first SC HoC amplifier cells of any one of the previous Examples comprises at least two inverter units coupled in series between an upper and a lower potential and a final inverter unit coupled to output terminals of the two inverter units. Each of the second SC HoC amplifier cells of any one of the previous Examples also comprises at least two inverter units coupled in series between the upper and lower potential and a final inverter unit coupled to output terminals of the two inverter units.

In Example 8, each inverter unit of Example 7 is coupled between terminals of a capacitor.

In Example 9, each of the first SC HoC amplifier cells of Example 7 or 8 comprises a respective capacitor coupled between an output of the respective final inverter unit and the common load Each of the second SC HoC amplifier cells of Example 7 or 8 comprises a respective capacitor coupled between an output of the respective final inverter unit and the common load.

In Example 10, the amplifier circuit of any one of the previous Examples comprises control circuitry configured to control an output voltage of the main amplifier circuit by controlling respective output voltage levels of the first SC HoC amplifier cells and/or control an output voltage of the peak amplifier circuit by controlling respective output voltage levels of the second SC HoC amplifier cells.

In Example 11, the amplifier circuit of any one of the previous Examples comprises control circuitry configured to generate, based on amplitude and/or phase modulation signals of a transmitter circuit, first control signals for driving input gates of inverter units of the first SC HoC amplifier cells, and second control signals for driving input gates of inverter units of the second SC HoC amplifier cells.

In Example 12, the control circuitry of Example 11 is configured to generate antiphase second control signals relative to the first control signals.

In Example 13, the amplifier circuit of any one of the previous Examples comprises control circuitry configured to (sequentially) operate the amplifier circuit in different operation modes. In a first operation mode, one or more SC HoC amplifier cells of the main amplifier circuit are configured to generate a first output voltage swing while the SC HoC amplifier stages of the peak amplifier circuit are off. In a (subsequent) second operation mode, all SC HoC amplifier cells of the main amplifier circuit are configured to generate the first output voltage swing and one or more SC HoC amplifier cells of the peak amplifier circuit are configured to generate the first output voltage swing. In a (subsequent) third operation mode, one or more SC HoC amplifier cells of the main amplifier circuit are configured to generate a second output voltage swing larger than the first output voltage swing and all SC HoC amplifier cells of the peak amplifier circuit are configured to generate the first output voltage swing. In a (subsequent) fourth operation mode, all SC HoC amplifier cells of the main amplifier circuit are configured to generate the second output voltage swing and one or more SC HoC amplifier cells of the peak amplifier circuit are configured to generate the second output voltage swing.

In Example 14, the control circuitry of Example, 13 is configured to (sequentially) operate the amplifier circuit in a (subsequent) fifth operation mode, wherein one or more SC HoC amplifier cells of the main amplifier circuit are configured to generate a third output voltage swing larger than the second output voltage swing and all SC HoC amplifier cells of the peak amplifier circuit are configured to generate the second output voltage swing. In a (subsequent) sixth operation mode, all SC HoC amplifier cells of the main amplifier circuit are configured to generate the third output voltage swing and one or more SC HoC amplifier cells of the peak amplifier circuit are configured to generate the third output voltage swing.

In Example 15, the amplifier circuit of any one of the previous Examples comprises control circuitry configured to (sequentially) operate the amplifier circuit in different operation modes. In a first operation mode, one or more SC HoC amplifier cells of the main amplifier circuit are configured to generate a first output voltage swing while the SC HoC amplifier stages of the peak amplifier circuit are off. In a (subsequent) second operation mode, one or more SC HoC amplifier cells of the main amplifier circuit are configured to generate a second output voltage swing larger than the first voltage output swing while the SC HoC amplifier stages of the peak amplifier circuit are off. In a (subsequent) third operation mode, all SC HoC amplifier cells of the main amplifier circuit are configured to generate the second output voltage swing and one or more SC HoC amplifier cells of the peak amplifier circuit are configured to generate the first output voltage swing. In a (subsequent) fourth operation mode, all SC HoC amplifier cells of the main amplifier circuit are configured to generate the second output voltage swing and one or more SC HoC amplifier cells of the peak amplifier circuit are configured to generate the second output voltage swing.

In Example 16, the amplifier circuit of any one of the previous Examples comprises control circuitry configured to (sequentially) operate the amplifier circuit in different operation modes. In a first operation mode, one or more SC HoC amplifier cells of the main amplifier circuit are configured to generate a first output voltage swing while the SC HoC amplifier cells of the peak amplifier circuit are off. In a (subsequent) second operation mode, one or more SC HoC amplifier cells of the main amplifier circuit are configured to generate a second output voltage swing larger than the first voltage output swing while the SC HoC amplifier cells of the peak amplifier circuit are off. In a (subsequent) third operation mode, one or more SC HoC amplifier cells of the main amplifier circuit are configured to generate a third output voltage swing larger than the second output voltage swing while the SC HoC amplifier cells of the peak amplifier circuit are off. In a (subsequent) fourth operation mode, all SC HoC amplifier cells of the main amplifier circuit are configured to generate the third output voltage swing and one or more SC HoC amplifier cells of the peak amplifier circuit are configured to generate the first output voltage swing. In a (subsequent) fifth operation mode, all SC HoC amplifier cells of the main amplifier circuit are configured to generate the third output voltage swing and one or more SC HoC amplifier cells of the peak amplifier circuit are configured to generate the second output voltage swing. In a (subsequent) sixth operation mode, all SC HoC amplifier cells of the main amplifier circuit are configured to generate the third output voltage swing and one or more SC HoC amplifier cells of the peak amplifier circuit are configured to generate the third output voltage swing.

Example 17 is a transmitter comprising the amplifier circuit of any one of the previous Examples.

Example 18 is a method of generating an amplified signal. The method includes generating a first amplifier output signal using a main amplifier circuit comprising a plurality of parallel first switched-capacitor, SC, house-of-cards, HoC, amplifier cells, generating a second amplifier output signal using at least one peak amplifier circuit comprising a plurality of parallel second SC HoC amplifier cells, and coupling the first and second amplifier output signals to a common load.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. An amplifier circuit, comprising
a main amplifier circuit comprising a plurality of first switched-capacitor, SC, house-of-cards, HoC, amplifier cells coupled in parallel between an input and an output of the main amplifier circuit;
at least one peak amplifier circuit comprising a plurality of second SC HoC amplifier cells coupled in parallel between an input and an output of the peak amplifier circuit;
wherein the output of the main amplifier circuit and the output of the peak amplifier circuit are coupled to a common load.

2. The amplifier circuit of claim 1, wherein each of the first and second SC HoC amplifier cells is configurable for different discrete output voltage levels.

3. The amplifier circuit of claim 1, wherein the peak amplifier circuit is configured to generate an antiphase output voltage relative to the main amplifier circuit.

4. The amplifier circuit of claim 1, wherein the output of the main amplifier circuit and the output of the peak amplifier circuit are coupled to the common load via a transformer balun.

5. The amplifier circuit of claim 1, wherein
the main amplifier circuit comprises N/2 SC HoC amplifier cells coupled in parallel between the input of the main amplifier circuit and the common load, and
the peak amplifier circuit comprises N/2 SC HoC amplifier cells coupled in parallel between the input of the peak amplifier circuit and the common load,
wherein N denotes an even integer.

6. The amplifier circuit of claim 5, wherein N≥8.

7. The amplifier circuit of claim 1, wherein each of the first SC HoC amplifier cells comprises
at least two inverter units coupled in series between an upper and a lower potential, and
a final inverter unit coupled to output terminals of the two inverter units, and
wherein each of the second SC HoC amplifier cells comprises
at least two inverter units coupled in series between the upper and lower potential, and
a final inverter unit coupled to output terminals of the two inverter units.

8. The amplifier circuit of claim 7, wherein each inverter unit is coupled between terminals of a capacitor.

9. The amplifier circuit of claim 7, further comprising
for each of the first SC HoC amplifier cells, a respective capacitor coupled between an output of the respective final inverter unit and the common load, and
for each of the second SC HoC amplifier cells, a respective capacitor coupled between an output of the respective final inverter unit and the common load.

10. The amplifier circuit of claim 1, comprising control circuitry configured to control an output voltage of the main amplifier circuit by controlling respective output voltage levels of the first SC HoC amplifier cells and/or control an output voltage of the peak amplifier circuit by controlling respective output voltage levels of the second SC HoC amplifier cells.

11. The amplifier circuit of claim 1, comprising control circuitry configured to generate, based on amplitude and/or phase modulation signals of a transmitter circuit,
first control signals for driving input gates of inverter units of the first SC HoC amplifier cells, and
second control signals for driving input gates of inverter units of the second SC HoC amplifier cells.

12. The amplifier circuit of claim 11, wherein the control circuitry is configured to generate antiphase second control signals relative to the first control signals.

13. The amplifier circuit of claim 1, comprising control circuitry configured to operate the amplifier circuit in different operation modes, wherein
in a first operation mode,
one or more SC HoC amplifier cells of the main amplifier circuit are configured to generate a first output voltage swing while the SC HoC amplifier stages of the peak amplifier circuit are off;
in a second operation mode,
all SC HoC amplifier cells of the main amplifier circuit are configured to generate the first output voltage swing and one or more SC HoC amplifier cells of the peak amplifier circuit are configured to generate the first output voltage swing;
in a third operation mode,
one or more SC HoC amplifier cells of the main amplifier circuit are configured to generate a second output voltage swing larger than the first output voltage swing and all SC HoC amplifier cells of the peak amplifier circuit are configured to generate the first output voltage swing;
in a fourth operation mode,
all SC HoC amplifier cells of the main amplifier circuit are configured to generate the second output voltage swing and one or more SC HoC amplifier cells of the peak amplifier circuit are configured to generate the second output voltage swing;

14. The amplifier circuit of claim 13, wherein the control circuitry is configured to operate the amplifier circuit
in a fifth operation mode,
one or more SC HoC amplifier cells of the main amplifier circuit are configured to generate a third output voltage swing larger than the second output voltage swing and all SC HoC amplifier cells of the peak amplifier circuit are configured to generate the second output voltage swing; and
in a sixth operation mode,
all SC HoC amplifier cells of the main amplifier circuit are configured to generate the third output voltage swing and one or more SC HoC amplifier cells of the peak amplifier circuit are configured to generate the third output voltage swing.

15. The amplifier circuit of claim 1, comprising control circuitry configured to operate the amplifier circuit in different operation modes, wherein
in a first operation mode,
one or more SC HoC amplifier cells of the main amplifier circuit are configured to generate a first output voltage swing while the SC HoC amplifier stages of the peak amplifier circuit are off;
in a second operation mode,
one or more SC HoC amplifier cells of the main amplifier circuit are configured to generate a second output voltage swing larger than the first voltage output swing while the SC HoC amplifier stages of the peak amplifier circuit are off,
in a third operation mode,
all SC HoC amplifier cells of the main amplifier circuit are configured to generate the second output voltage swing and one or more SC HoC amplifier cells of the peak amplifier circuit are configured to generate the first output voltage swing.
in a fourth operation mode,
all SC HoC amplifier cells of the main amplifier circuit are configured to generate the second output voltage swing and one or more SC HoC amplifier cells of the peak amplifier circuit are configured to generate the second output voltage swing.

16. The amplifier circuit of claim 1, comprising control circuitry configured to operate the amplifier circuit in different operation modes, wherein
in a first operation mode,
one or more SC HoC amplifier cells of the main amplifier circuit are configured to generate a first output voltage swing while the SC HoC amplifier cells of the peak amplifier circuit are off;
in a second operation mode,
one or more SC HoC amplifier cells of the main amplifier circuit are configured to generate a second output voltage swing larger than the first voltage output swing while the SC HoC amplifier cells of the peak amplifier circuit are off;
in a third operation mode,
one or more SC HoC amplifier cells of the main amplifier circuit are configured to generate a third output voltage swing larger than the second output voltage swing while the SC HoC amplifier cells of the peak amplifier circuit are off;
in a fourth operation mode,
all SC HoC amplifier cells of the main amplifier circuit are configured to generate the third output voltage swing and one or more SC HoC amplifier cells of the peak amplifier circuit are configured to generate the first output voltage swing.
in a fifth operation mode,
all SC HoC amplifier cells of the main amplifier circuit are configured to generate the third output voltage swing and one or more SC HoC amplifier cells of the peak amplifier circuit are configured to generate the second output voltage swing.
in a sixth operation mode,
all SC HoC amplifier cells of the main amplifier circuit are configured to generate the third output voltage swing and one or more SC HoC amplifier cells of the peak amplifier circuit are configured to generate the third output voltage swing.

17. A transmitter comprising the amplifier circuit of claim 1.

18. A method of generating an amplified signal, comprising
generating a first amplifier output signal using a main amplifier circuit comprising a plurality of parallel first switched-capacitor, SC, house-of-cards, HoC, amplifier cells;
generating a second amplifier output signal using at least one peak amplifier circuit comprising a plurality of parallel second SC HoC amplifier cells; and
coupling the first and second amplifier output signals to a common load.
